(19) United States
(12) Patent Application Publication
(10) Pub. No.: US 2016/0056143 A1
(43) Pub. Date: Feb. 25, 2016

(54) LIGHT EMITTING DEVICE PACKAGE

(71) Applicant: SAMSUNG ELECTRONICS CO., LTD., Suwon-si (KR)

(72) Inventors: Jung Kyu PARK, Seoul (KR); Young Geun JUN, Seoul (KR); Su Hyun JUNG, Daegu (KR)

(21) Appl. No.: 14/750,417

(22) Filed: Jun. 25, 2015

(30) Foreign Application Priority Data
Aug. 20, 2014 (KR) 10-2014-0108441

(51) Int. Cl. H01L 27/02; H01L 29/866; H01L 27/15; H01L 33/60; H01L 33/58; H01L 33/62; H01L 33/54

(52) U.S. Cl. CPC H01L 27/0255; H01L 33/62; H01L 29/866; H01L 33/54; H01L 33/60; H01L 33/58; H01L 27/156

(57) ABSTRACT

A light emitting device package include: a lead frame having one surface with a recess portion provided therein and including a first mounting region positioned on the one surface and a second mounting region positioned in the recess portion; a light emitting device mounted on the first mounting region and electrically connected to the lead frame; and a Zener diode mounted on the second mounting region and connected to the lead frame by a wire. The wire is positioned within the recess portion and is disposed to have a height lower than the first mounting region.

### CROSS-REFERENCE TO RELATED APPLICATION

This application claims the priority to Korean Patent Application No. 10-2014-0108441 filed on Aug. 20, 2014, with the Korean Intellectual Property Office, the disclosure of which is incorporated herein by reference.

### BACKGROUND

The present disclosure relates to a light emitting device package.

In order to protect light emitting device (LED) chips, vulnerable to static electricity, Zener diodes are generally used as electrostatic discharge (ESD) preventing devices. On lead frames on which an LED chip is mounted, a Zener diode is commonly mounted to be adjacent to and alongside the LED chip.

Zener diodes are formed of silicon which absorbs light, having a problem of reducing luminous efficiency (optical interference). Also, wire bonding may be used for forming electrical connections, and here, efficiency of a phosphor application process is degraded by wires (mechanical interference).

The reduction in optical efficiency may be overcome by preparing an extra space for mounting a Zener diode, but preparation of an extra space within a package disadvantageously increases package size. Such an increase in size is directly related to undesirable increases in manufacturing costs.

### SUMMARY

An aspect of the present disclosure may provide a scheme removing optical and mechanical interference of a Zener diode while not increasing a size of a package.

According to an aspect of the present disclosure, a light emitting device package may include: a lead frame having a first surface with a recess portion provided therein and including a first mounting region positioned on the first surface and a second mounting region positioned in the recess portion; a light emitting device mounted on the first mounting region and electrically connected to the lead frame; and a Zener diode mounted on the second mounting region and connected to the lead frame by a wire. The wire may be positioned within the recess portion and is disposed to have a height lower than the first mounting region.

The light emitting device may be disposed on the Zener diode and the wire.

The recess portion may be disposed to surround the first mounting region.

The light emitting device package may further include an encapsulant filling the recess portion and covering the Zener diode and the wire.

The encapsulant may include a reflective powder.

The recess portion may be recessed from the first surface of the lead frame and have a bottom surface forming a step with respect to the first mounting region.

A bottom surface of the second mounting region may have a level lower than the other region of the bottom surface of the recess portion.

The Zener diode may have a first electrode disposed on a lower surface thereof and a second electrode disposed on an upper surface thereof, and the first electrode may be connected to one region of the lead frame through the bottom surface of the recess portion and the second electrode may be connected to the other region of the lead frame through the wire.

The Zener diode may be attached to the bottom surface of the second mounting region by a conductive material.

The second mounting region may be a region penetrating through the lead frame, and may include a conductive material partially filling the penetrated region to provide the bottom surface of the second mounting region.

The Zener diode may have a first electrode disposed on a lower surface thereof and a second electrode disposed on an upper surface thereof, and the first electrode may be connected to one region of the lead frame through the conductive material and the second electrode may be connected to the other region of the lead frame through the wire.

The lead frame may include separated first and second lead frames, and the recess portion may be disposed in at least one of the first and second lead frames.

The second mounting region may be positioned on one side of either of the first and second lead frames.

The light emitting device package may further include an encapsulant filling the recess portion and covering the Zener diode and the wire, and the encapsulant may bind the first and second lead frames.

According to another aspect of the present disclosure, a light emitting device package may include: first and second lead frames disposed to be spaced apart from one another; a light emitting device disposed on at least one of the first and second lead frames; a Zener diode disposed on the second lead frame and connected to the first lead frame by a wire; and an encapsulant binding the first and second lead frames. The Zener diode may be mounted in a region penetrating through the lead frame on a bottom surface of a recess portion provided in the second lead frame, and the wire may be positioned within the recess portion to have a level lower than the light emitting device.

According to another aspect of the present disclosure, a package may include a lead frame having a recess, a Zener diode disposed in the recess of the lead frame, and a light emitting device disposed on the Zener diode.

One electrode of the Zener diode may be electrically connected to the lead frame via a wire disposed in the recess and covered by the light emitting device.

The package may further include an encapsulant filling the recess and covering the Zener diode and the wire. The encapsulant may contain a light reflective ceramic material.

The package may further include a light transmissive lens unit. The lens unit may not contact any of the Zener diode and the wire. The lens unit may contain a phosphor.

The lead frame may include a hole penetrating through the bottom of the recess and the Zener diode may be disposed in the hole.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view schematically illustrating a light emitting device package according to an exemplary embodiment of the present disclosure;

FIG. 2 is a cross-sectional view taken along line A-A′ of FIG. 1;

FIG. 3A is a perspective view schematically illustrating a lead frame of FIG. 1;

FIG. 3B is a cross-sectional view taken along line B-B′ of FIG. 3A;

FIG. 4A is a perspective view schematically illustrating provision of a Zener diode and a wire in a state of FIG. 3A;

FIG. 4B is a cross-sectional view taken along line C-C′ of FIG. 4A;

FIG. 5A is a perspective view schematically illustrating provision of a light emitting device in a state of FIG. 4A;

FIG. 5B is a cross-sectional view taken along line D-D′ of FIG. 5A;

FIG. 6 is a perspective view schematically illustrating a light emitting device package according to another exemplary embodiment of the present disclosure;

FIG. 7 is a cross-sectional view taken along line E-E′ of FIG. 6;

FIG. 8A is a perspective view schematically illustrating a lead frame of FIG. 6;

FIG. 8B is a cross-sectional view taken along line F-F′ of FIG. 8A;

FIG. 9 is a perspective view schematically illustrating a light emitting device package according to another exemplary embodiment of the present disclosure;

FIG. 10 is a cross-sectional view taken along line G-G′ of FIG. 9;

FIG. 11 is a CIE 1931 color space chromaticity diagram;

FIGS. 12 through 14 are cross-sectional views illustrating various examples of light emitting diode (LED) chips employable in a light emitting device according to an exemplary embodiment of the present disclosure;

FIG. 15 is an exploded perspective view schematically illustrating a lighting device (bulb type) according to an exemplary embodiment of the present disclosure;

FIG. 16 is an exploded perspective view schematically illustrating a lighting device (L lamp type) according to an exemplary embodiment of the present disclosure; and

FIG. 17 is an exploded perspective view schematically illustrating a lighting device (planar type) according to an exemplary embodiment of the present disclosure.

### DETAILED DESCRIPTION

Hereinafter, exemplary embodiments of the present disclosure will be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

These embodiments are provided so that this disclosure will be thorough and complete, and will fully convey the scope of the invention to those skilled in the art. In the drawings, the shapes and dimensions may be exaggerated for clarity. Thus, in the drawings, the shapes and dimensions of elements may be exaggerated for clarity, and the same reference numerals will be used throughout to designate the same or like elements. In this disclosure, terms such as “above”, “upper portion”, “upper surface”, “below”, “lower portion”, “lower surface”, “lateral surface”, and the like, are determined based on the drawings, and in actuality, the terms may be changed according to a direction in which a device or an element is disposed.

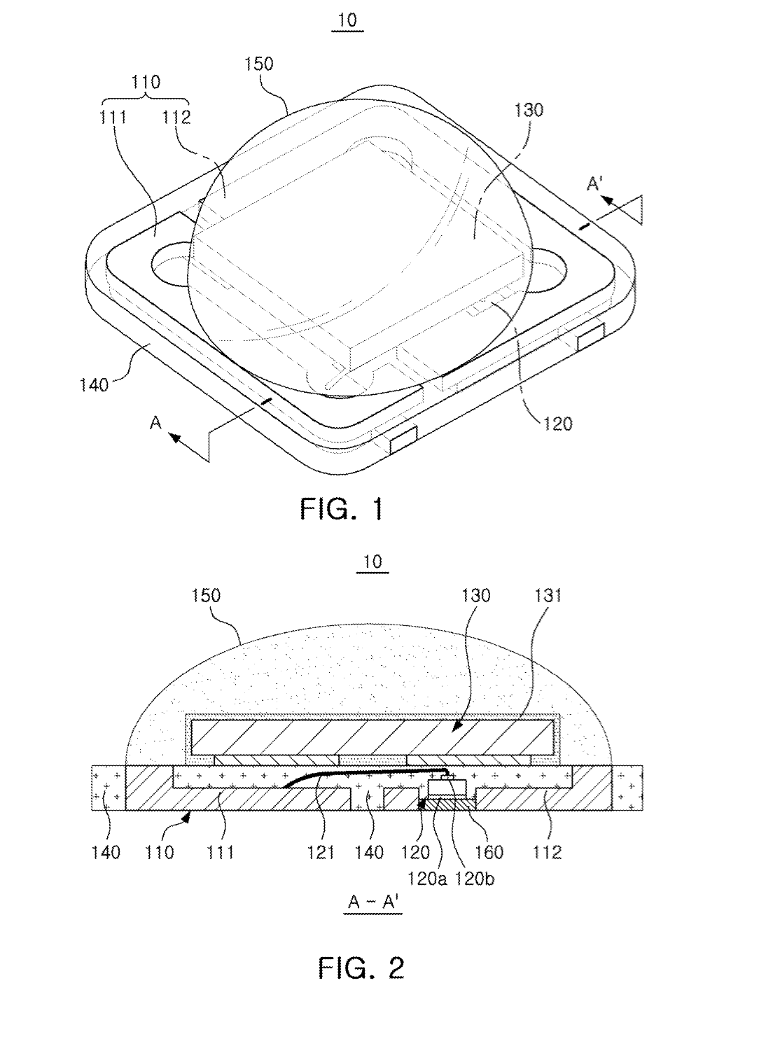

A light emitting device package according to an exemplary embodiment of the present disclosure will be described with reference to FIGS. 1 and 2. FIG. 1 is a perspective view schematically illustrating a light emitting device package according to an exemplary embodiment of the present disclosure, and FIG. 2 is a cross-sectional view taken along line A-A′ of FIG. 1.

Referring to FIGS. 1 and 2, a light emitting device package 10 according to an exemplary embodiment may include a lead frame 110 including a first mounting region 110a and a second mounting region 110b, a Zener diode 120 mounted on the second mounting region 110b, and a light emitting device 130 mounted on the first mounting region 110a.

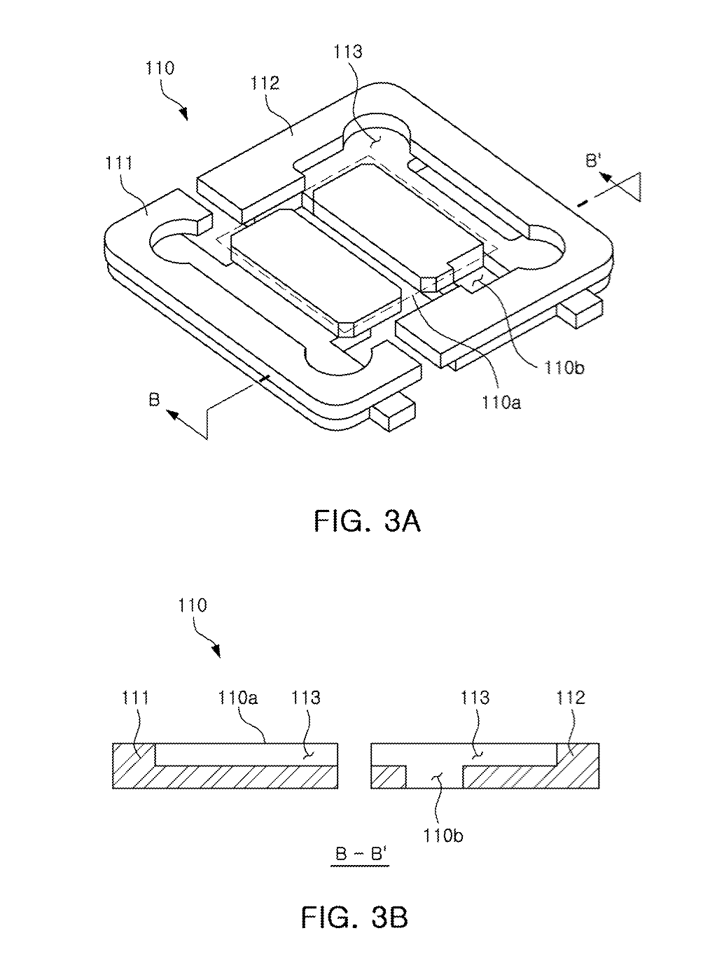

FIGS. 3A and 3B schematically illustrate the lead frame 110. The lead frame 110 may include at least a pair of first lead frame 111 and a second lead frame 112 which are separated. The lead frame 110 may have an overall quadrangular plate structure.

The lead frame 110 may have a first surface and a second surface opposite to each other. The first surface may define a top surface of the lead frame 110 and the second surface may define a bottom surface of the lead frame 110.

The lead frame 110 may have a first mounting region 110a positioned on the first surface thereof. A light emitting device 130 described hereinafter may be mounted on the first mounting region 110a.

The first mounting region 110a may be defined as a central portion of the first surface, namely, a central portion of the top surface on which the first lead frame 111 and the second lead frame 112 face one another.

Also, the first mounting region 110a, rather than being positioned over the first and second lead frames 111 and 112 facing one another as illustrated, may be positioned on one side of either of the first and second lead frames 111 and 112.

The lead frame 110 may have a recess portion 113 formed on the first surface and recessed to a predetermined depth from the first surface. The recess portion 113 may have a bottom surface recessed from the first surface of the lead frame 110 to form a step with respect to the first mounting region 110a.

The recess portion 113 may be disposed to traverse the first and second lead frames 111 and 112 and surround the first mounting region 110a. Namely, the lead frame 110 may have a structure in which the recess portion 113 surrounds the first mounting region 110a.

In the present exemplary embodiment, it is illustrated that the recess portion 113 is provided along the circumference of the first mounting region 110a, but the position of the recess portion 113 is not limited thereto. For example, the recess portion 113 may be provided in at least one of the first and second lead frames 111 and 112.

The recess portion 113 may accommodate a wire 121 therein.

The lead frame 110 may have the second mounting region 110b together with the first mounting region 110a. The second mounting region 110b may be positioned within the recess portion 113. In detail, the second mounting region 110b may be provided as a region penetrating through the bottom surface of the recess portion 113 on one side of either of the first and second lead frames 111 and 112.

The Zener diode 120 described hereinafter may be mounted in the second mounting region 110b.

The lead frame 110 according to the present exemplary embodiment may have a structure in which the first mounting region 110a is positioned on the first surface corresponding to the top surface, the recess portion 113 is provided along the circumference of the mounting region 110a and a bottom surface of the recess portion 113 forms a step with respect to the first mounting region 110a, and the second mounting region 110b is provided to penetrate through the bottom surface of the recess portion 113.

The lead frame 110 may be formed of a material having excellent electrical conductivity and light reflectivity. A material of the lead frame 110 may include, for example, a metal such as silver (Ag), aluminum (Al), copper (Cu), nickel (Ni), gold (Au), chromium (Cr), titanium (Ti), or alloys thereof, but the material of the lead frame 110 is not limited thereto.

The Zener diode 120 may be mounted in the second mounting region 110b formed as a hole penetrating through the lead frame 110. The Zener diode 120 may be electrically connected to the lead frame 110 through the wire 121.

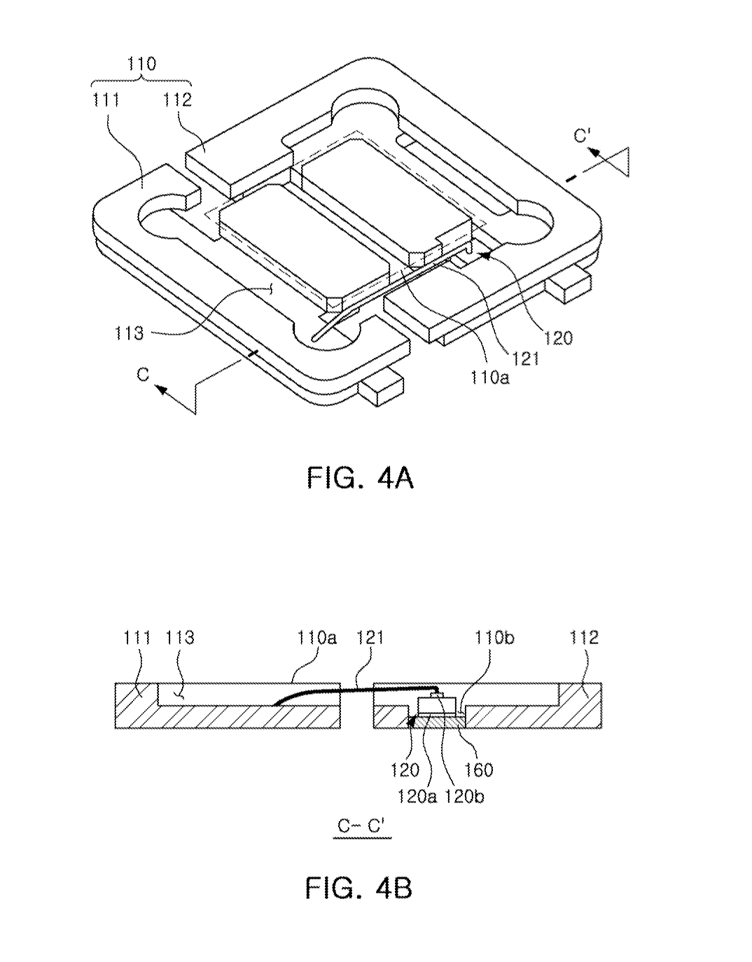

As illustrated in FIGS. 4A and 4B, the Zener diode 120 may be attached to an interior of the second mounting region 110b of the second lead frame 112 through, for example, a conductive material 160.

The conductive material 160 may partially fill a lower portion of the second mounting region 110b, the penetration region, to provide a bottom surface of the second mounting region 110b. A surface of the conductive material 160 exposed from the second surface of the lead frame 110 may substantially be coplanar with the other surface of the lead frame 110. The conductive material 160 may be, for example, silver (Ag) epoxy, but the material of the conductive material 160 may not be limited thereto.

The Zener diode 120 may include a first electrode 120a disposed on a lower surface thereof and a second electrode 120b disposed on an upper surface thereof.

The first electrode 120a may be connected to a region of the lead frame 110, for example, the second lead frame 112 on which the second mounting region 110b is formed, through the conductive material 160.

The second electrode 120b may be connected to the wire 121 so as to be connected to another region of the lead frame, for example, the first lead frame 111.

The wire 121 may be accommodated in the recess portion 113 and extend to the first lead frame 111 along the recess portion 113. In this case, the wire 121 may be maintained to be as low as possible through an ultra-low loop (ULL) scheme. Namely, the wire 121 may be positioned within the recess 113 and extend with a height lower than the first mounting region 110a.

Thus, the Zener diode 120 mounted in the second mounting region 110b of the lead frame 110 and the wire 121 positioned within the recess portion 113 of the lead frame 110 may be positioned at a level lower than the first mounting region 110a.

In this manner, in the present exemplary embodiment, the Zener diode 120 and the wire 121 may be embedded, for example, within the lead frame 110, and thus, the Zener diode 120 and the wire 121 do not protrude from the first surface corresponding to the top surface of the lead frame 110. In detail, the Zener diode 120 and the wire 121 are disposed to be lower than the first mounting region 110a, rather than protruding from the first mounting region 110a.

The recess portion 113 may be filled with an encapsulant 140, and the encapsulant 140 may hermetically seal the Zener diode 120 and the wire 121, thus fixing the Zener diode 120 and the wire 121 in place and providing protection thereto from an external environment.

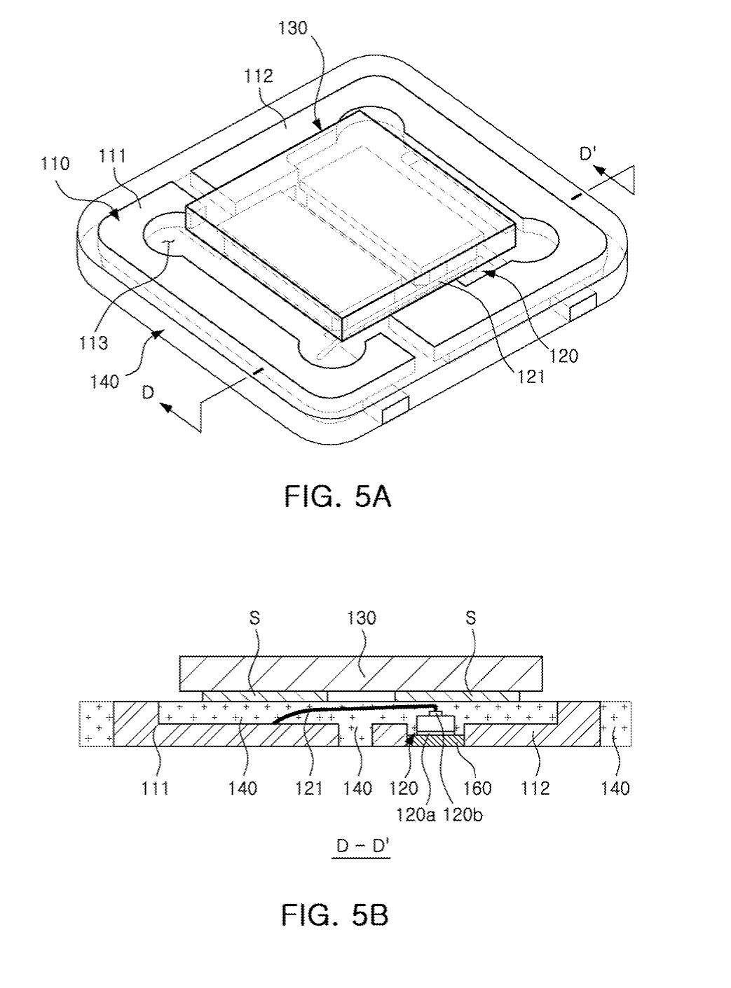

As illustrated in FIGS. 5A and 5B, the encapsulant 140 fills the recess portion 113 and allows the lead frame 110 to be embedded therein, thus surrounding the lead frame 110. Also, the encapsulant 140 may bind the first and second lead frames 111 and 112. In this case, the encapsulant 140 may serve as a type of package body fixing and supporting the lead frame 110.

An upper surface of the encapsulant 140 may have the substantially same horizontal level as that of the first mounting region 110a. Thus, the encapsulant 140 may expose the first mounting region 110a.

In order to be electrically connected with an external power source, the lead frame 110 may be outwardly exposed from a bottom surface or a top surface of the encapsulant 140. Also, since the lead frame 110 is directly exposed to the bottom surface or top surface of the encapsulant 140, heat dissipation efficiency may be enhanced.

The encapsulant 140 may be formed by injecting a resin such as polycarbonate (PC), polymethylmethacrylate (PMMA), acryl, or ABS, or an epoxy into the recess portion 113 and solidifying the same.

The encapsulant 140 may contain a reflective powder. The reflective powder may include, for example, a highly reflective metal powder, a white ceramic powder such as SiO₂, TiO₂ or Al₂O₃, or the like.

The encapsulant 140 may be selectively provided. Thus, the encapsulant 140 may be omitted.

The light emitting device 130 may be mounted on the first mounting region 110a. The light emitting device 130 may be electrically connected to the first and second lead frames 111 and 112 in a flipchip bonding manner using solder (S), for example. The light emitting device 130 may be disposed on the encapsulant 140 covering the Zener diode 120 and the wire 121.

The light emitting device 130 may be a photoelectric device generating light of a predetermined wavelength by driving power applied from the outside. For example, the light emitting device 130 may include a semiconductor light emitting diode (LED) chip including an n-type semiconductor layer, a p-type semiconductor layer, and an active layer disposed therebetween.

The light emitting device 130 may emit blue light, green light, and red light according to combinations with a contained material or phosphors, and may emit white light, ultraviolet light, and the like.

The light emitting device 130 may be coated with a wavelength conversion layer 131. The wavelength conversion layer 131 may be formed by containing at least one or more types of phosphors emitting light of different wavelengths upon being excited by light generated by the light emitting device 130, in a light-transmissive resin, for example. Accordingly, light of various colors including white light may be adjusted to be emitted.

For example, when the light emitting device 130 emits blue light, blue light may be combined with yellow, green, red, and orange phosphors to emit white light. Also, at least one of light emitting devices 130 emitting purple, blue, green, red, or infrared light may be provided. In this case, the light emitting device 130 may control a color rendering index (CRI) to range from the level of light emitted by a sodium-vapor (Na) lamp (40) to the level of sunlight (100), or the like, and control a color temperature ranging from 2000K to 20000K to generate various levels of white light. If necessary, the light emitting device 130 may generate visible light having purple, blue, green, red, orange colors, or infrared light to adjust an illumination color according to a surrounding atmosphere or mood. Also, the light emitting device 130 may generate light having a special wavelength stimulating plant growth.

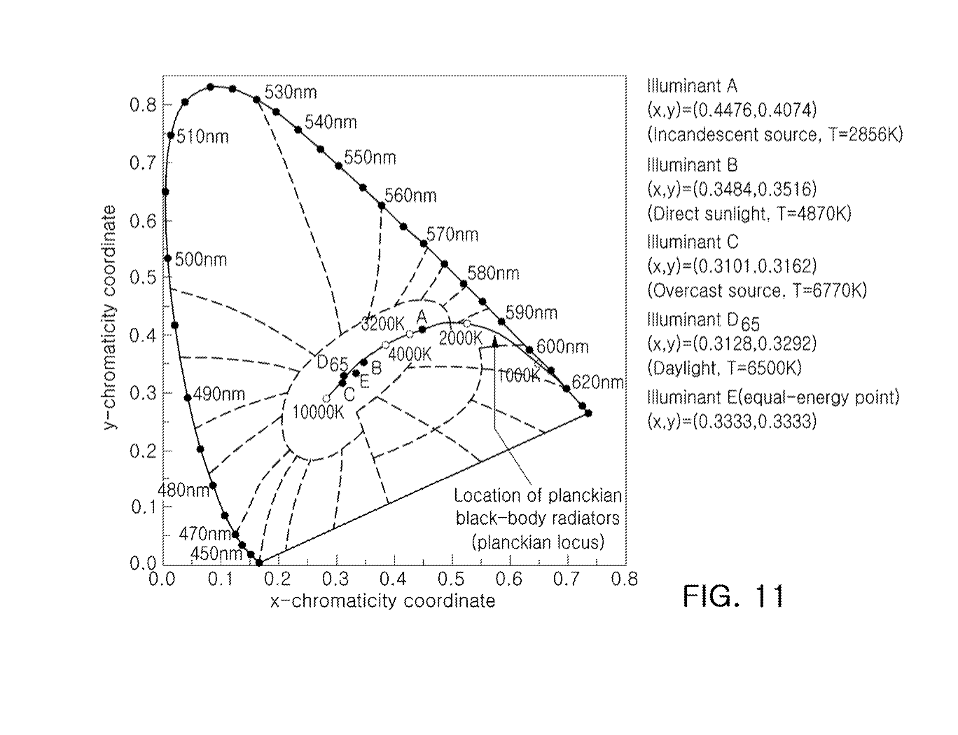

White light generated by combining yellow, green, red phosphors with a blue light emitting device and/or by combining at least one of a green light emitting device and a red light emitting device therewith, may allow for two or more peak wavelengths and positioning in a segment linking (x, y) coordinates (0.4476, 0.4074), (0.3484, 0.3516), (0.3101, 0.3162), (0.3128, 0.3292), (0.3333, 0.3333) of a CIE 1931 chromaticity diagram illustrated in FIG. 11. Alternatively, white light may be positioned in a region surrounded by a spectrum of black body radiation and the segment. A color temperature of white light corresponds to a range from about 2000K to about 20000K.

Phosphors may have the following empirical formulas and colors:

Oxides: Yellow and green Y₃Al₅O₁₂:Ce, Tb₃Al₅O₁₂:Ce, Lu₃Al₅O₁₂:Ce

Silicates: Yellow and green (Ba,Sr)₂SiO₄:Eu, yellow and orange (Ba,Sr)₃SiO₅:Ce

Nitrides: Green β-SiAlON:Eu, yellow La₂Si₆N₁₁:Ce, orange α-SiAlON:Eu, red CaAlSiN³:Eu, Sr₂Si₅N₈:Eu, SrSiAl₄N₇: Eu

Fluorides: KSF-based red K₂SiF₆:Mn4+

Phosphor compositions should basically conform with Stoichiometry, and respective elements may be substituted with different elements of respective groups of the periodic table. For example, strontium (Sr) may be substituted with barium (Ba), calcium (Ca), magnesium (Mg), and the like, of alkali earths, and yttrium (Y) may be substituted with terbium (Tb), Lutetium (Lu), scandium (Sc), gadolinium (Gd), and the like. Also, europium (Eu), an activator, may be substituted with cerium (Ce), terbium (Tb), praseodymium (Pr), erbium (Er), ytterbium (Yb), and the like, according to a desired energy level, and an activator may be applied alone, or a coactivator, or the like, may be additionally applied to change characteristics.

Also, materials such as quantum dots, or the like, may be applied as materials that replace phosphors, and phosphors and quantum dots may be used in combination or alone.

A quantum dot may have a structure including a core (diameter of 3 nm to 10 nm) such as CdSe or InP, a shell (thickness of 0.5 nm to 2 nm) such as ZnS or ZnSe, and a ligand for stabilizing the core and the shell, and may realize various colors according to size.

A lens unit 150 may be provided on the first surface of the lead frame 110 to cover the light emitting device 130 (including the wavelength conversion layer 131).

The lens unit 150 may be formed of, for example, a light-transmissive resin. The lens unit 150 may cover the light emitting device 130 including the wavelength conversion layer 131 to protect the same from an external environment and adjust a beam angle of light from the light emitting device 130.

The lens unit 150 may contain a phosphor or a light diffusion material. When the lens unit 150 contains a phosphor, the wavelength conversion layer 131 coated on the light emitting device 130 may be omitted according to circumstances. In a case in which the lens unit 150 contains a phosphor in addition to the wavelength conversion layer 131, the phosphor contained in the lens unit 150 may be a type of phosphor different from that of a phosphor of the wavelength conversion layer 131.

The lens unit 150 may be selectively provided. Thus, the lens unit 150 may be omitted according to exemplary embodiments.

In this manner, the light emitting device package according to the present exemplary embodiment has a chip-on-board (COB)-type structure in which the light emitting device 130 and the Zener diode 120 are mounted in the same direction (the upper surface direction) on the lead frame 110, and in particular, since the region in which the Zener diode 120 is mounted and the region in which the wire 121 passes are positioned below the flat surface on which the light emitting device 130 is mounted, the Zener diode 120 and the wire 121 do not protrude from the flat surface, and thus optical and mechanical interference thereof may be prevented.

In addition, since the Zener diode 120 and the wire 121 are embedded in the lead frame 110, the size of the package may be reduced to be equivalent to the size of the lead frame 110, facilitating a reduction in the size and thickness of the package.

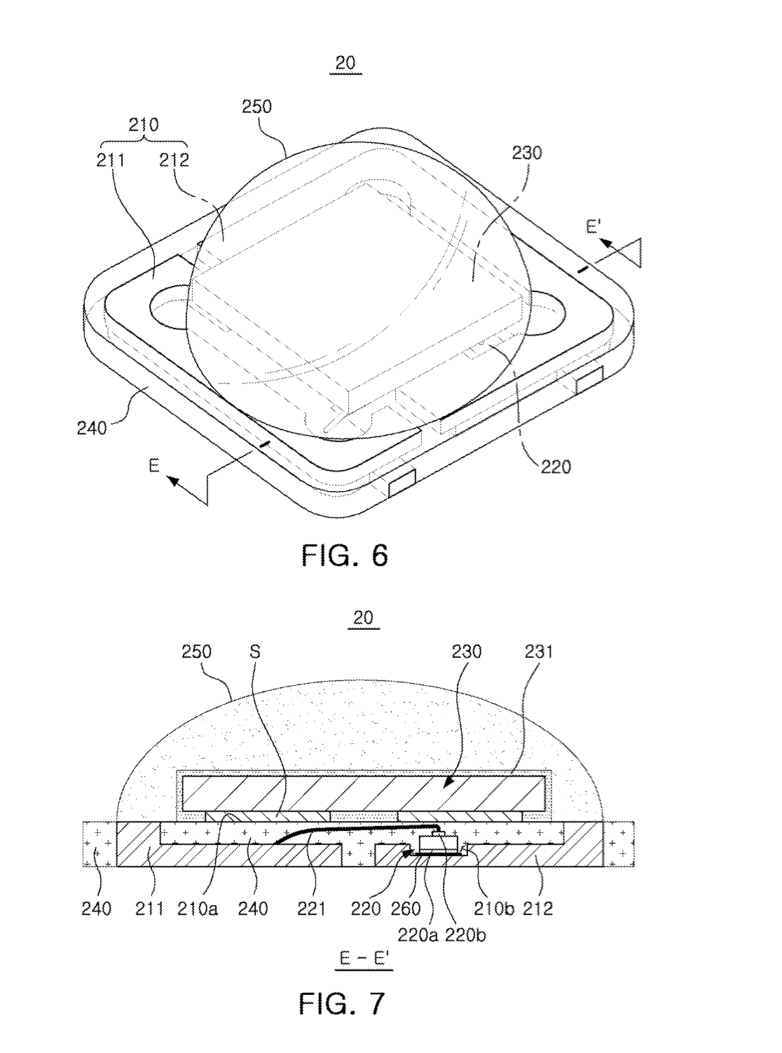

A light emitting device package according to another exemplary embodiment will be described with reference to FIGS. 6 through 8. FIG. 6 is a perspective view schematically illustrating a light emitting device package according to another exemplary embodiment of the present disclosure, and FIG. 7 is a cross-sectional view taken along line E-E′ of FIG. 6.

A configuration of the light emitting device package according to the exemplary embodiment illustrated in FIGS. 6 through 8 is substantially the same as that of the exemplary embodiment illustrated in FIGS. 1 through 5, except for a structure of a lead frame having a second mounting region. Thus, hereinafter, descriptions of the same components as those of the previous exemplary embodiment will be omitted and the lead frame will be largely described.

Referring to FIGS. 6 and 7, a light emitting device package 20 according to the present exemplary embodiment may include a lead frame 210 having a first mounting region 210a and a second mounting region 210b, a Zener diode 220 mounted on the second mounting region 210b, and a light emitting device 230 mounted on the first mounting region 210a.

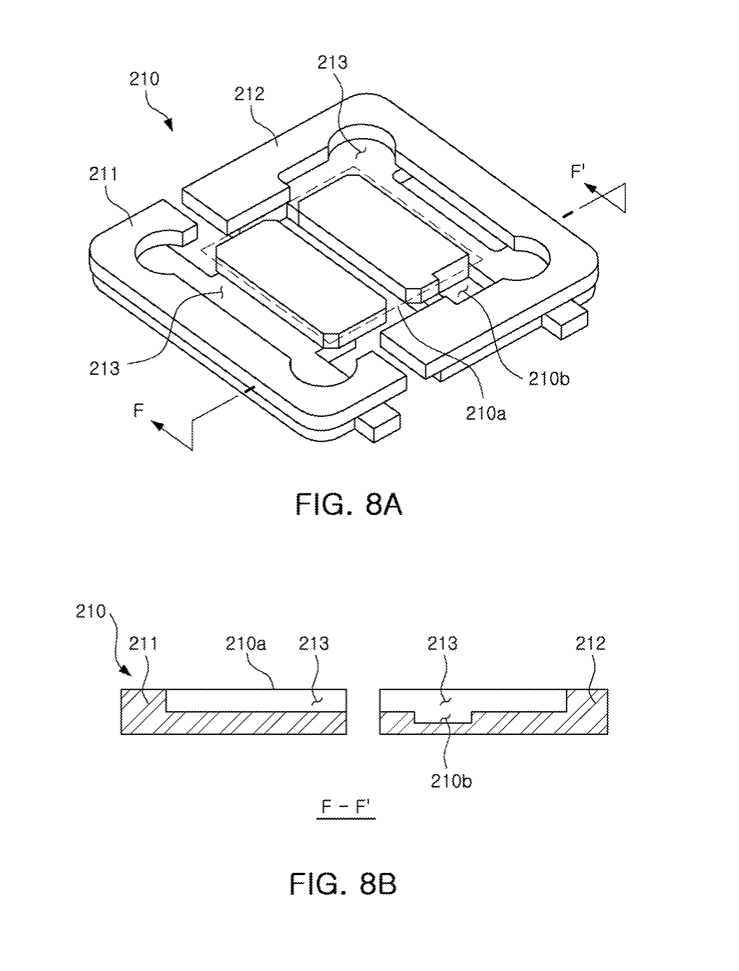

FIGS. 8A and 8B schematically illustrating the lead frame 210. The lead frame 210 may include at least a first lead frame 211 and a second lead frame 212 formed as a pair and separated. The lead frame 210 may have an overall quadrangular plate structure.

The lead frame 210 may have a first surface and a second surface opposite to each other. The first surface may define a top surface of the lead frame 210 and the second surface may define a bottom surface of the lead frame 210.

The lead frame 210 may have a first mounting region 210a positioned on the first surface thereof. The lead frame 210 may have a recess portion 213 recessed to a predetermined depth along the circumference of the first mounting region 210a.

The recess portion 213 may have a bottom surface recessed from the first surface of the lead frame 210 to form a step with respect to the first mounting region 210a. The recess portion 213 may accommodate a wire 221 therein.

The lead frame 210 may have the second mounting region 210b together with the first mounting region 210a. The second mounting region 210b may be positioned within the recess portion 213.

In detail, the second mounting region 210b may be recessed from one side of either of the first and second lead frames 211 and 212 to a predetermined depth of the bottom surface of the recess portion 213. A bottom surface of the second mounting region 210b may have a level lower than other regions of the bottom surface of the recess portion 213. Alternatively, although not shown in FIGS. 8A and 8B, the second mounting region 210b may have a same level as other regions of the bottom surface of the recess portion 213. Also, with respect to the second surface of the lead frame 210, the bottom surface of the second mounting region 210b may be disposed in a position lower than the first mounting region 210a. The Zener diode 220 may be mounted on the second mounting region 210b.

The lead frame 210 according to the present exemplary embodiment may have a structure in which the first mounting region 210a is positioned on the first surface corresponding to the top surface of the lead frame 210, the recess portion 213 is provided along the circumference of the first mounting region 210a and a bottom surface of the recess portion 213 forms a step with respect to the first mounting region 210a, and the second mounting region 210b is recessed from the bottom surface of the recess portion 213 to form a step.

The lead frame 210 may be formed of a material having excellent electrical conductivity and light reflectivity. A material of the lead frame 110 may include, for example, a metal such as silver (Ag), aluminum (Al), copper (Cu), nickel (Ni), gold (Au), chromium (Cr), titanium (Ti), or alloys thereof, but the material of the lead frame 210 is not limited thereto.

As illustrated in FIG. 7, the Zener diode 220 may be mounted in the second mounting region 210b and may be connected to the wire 221 so as to be electrically connected to the lead frame 210.

The Zener diode 220 may include a first electrode 220a disposed on a lower surface thereof and a second electrode 220b disposed on an upper surface thereof.

The first electrode 220a may be connected to a region of the lead frame 210, for example, to the second lead frame 212 provided with the second mounting region 210b. In this case, the Zener diode 220 may be attached to the bottom surface of the second mounting region 210b by a conductive material 260, for example.

The second electrode 220b may be connected to a different region of the lead frame 210, for example, the first lead frame 211, through the wire 221.

The wire 221 may be accommodated in the recess portion 213 and extend to the first lead frame 211 along the recess portion 213. In this case, the wire 221 may be maintained to be as low as possible through an ultra-low loop (ULL) scheme.

Thus, the Zener diode 220 mounted in the second mounting region 210b of the lead frame 210 and the wire 221 accommodated within the recess portion 213 of the lead frame 210 may be positioned at a level lower than the first mounting region 210a. Namely, the Zener diode 220 and the wire 221 may be embedded, for example, within the lead frame 210, and thus, the Zener diode 220 and the wire 221 do not protrude from the first surface corresponding to the top surface of the lead frame 210.

The recess portion 213 may be filled with an encapsulant 240, and the encapsulant 240 may fix the Zener diode 220 and the wire 221 for the protection thereof from an external environment.

Also, the encapsulant 240 fills the recess portion 213 and allows the lead frame 210 to be embedded therein, thus surrounding the lead frame 210. In this case, the encapsulant 240 may serve as a type of package body fixing and supporting the lead frame 210.

The configuration and structure of the encapsulant 240 are substantially the same as those of the encapsulant 140 of FIG. 1. Thus, detailed descriptions thereof will be omitted.

The light emitting device 230 may be mounted on the first mounting region 210a. The light emitting device 230 may be electrically connected to the first and second lead frames 211 and 212 in a flipchip bonding manner using solder (S), for example. The light emitting device 230 may be disposed on the encapsulant 240 covering the Zener diode 220 and the wire 221.

The light emitting device 230 may be coated with a wavelength conversion layer 231. The wavelength conversion layer 231 may be formed by containing at least one or more types of phosphors emitting light of different wavelengths upon being excited by light generated by the light emitting device 230, in a light-transmissive resin, for example. Accordingly, light of various colors including white light may be adjusted to be emitted.

A lens unit 250 may be provided on the first surface of the lead frame 210 to cover the light emitting device 230.

The lens unit 250 may be formed of, for example, a light-transmissive resin. The lens unit 250 may cover the light emitting device 230 including the wavelength conversion layer 231 to protect the same from an external environment and adjust a beam angle of light from the light emitting device 230.

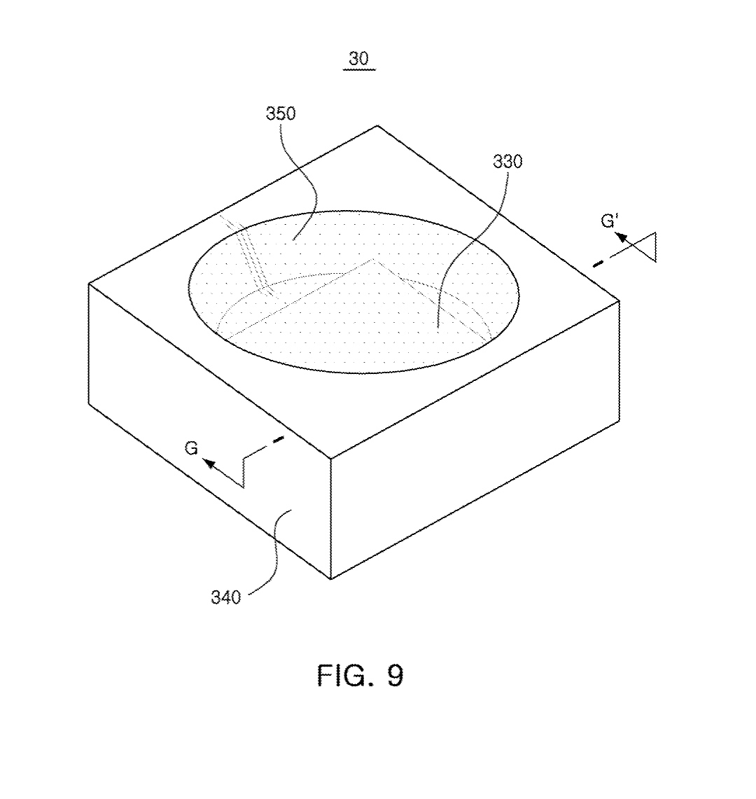

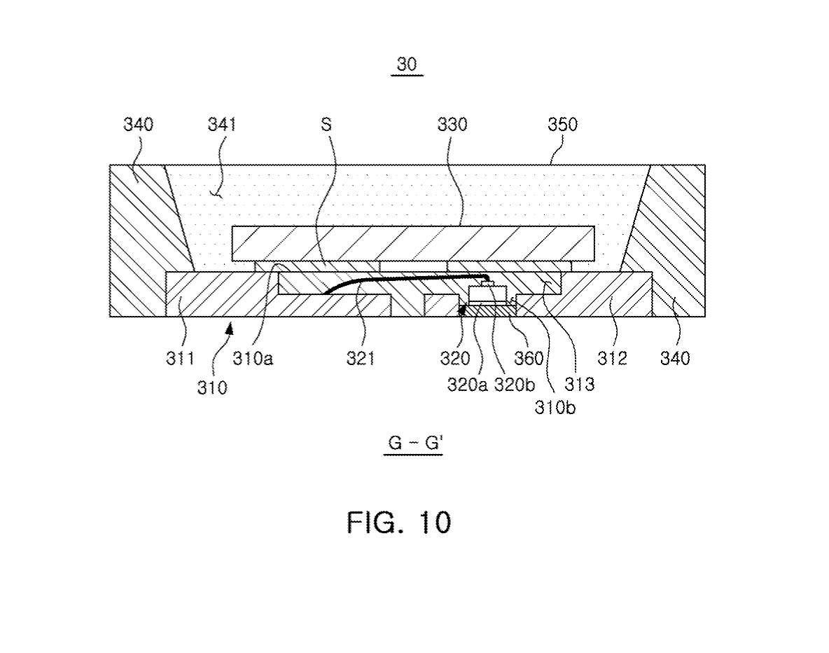

A light emitting device package according to another exemplary embodiment will be described with reference to FIGS. 9 and 10. FIG. 9 is a perspective view schematically illustrating a light emitting device package according to another exemplary embodiment of the present disclosure, and FIG. 10 is a cross-sectional view taken along line G-G′ of FIG. 9.

A configuration of the light emitting device package according to the exemplary embodiment illustrated in FIGS. 9 and 10 is basically substantially the same as that of the exemplary embodiment illustrated in FIGS. 1 through 5, except for a configuration of a package body surrounding a lead frame. Thus, hereinafter, descriptions of the same components as those of the previous exemplary embodiment will be omitted and the package body will be largely described.

Referring to FIGS. 9 and 10, a light emitting device package 30 according to the present exemplary embodiment may include a lead frame 310 having a first mounting region 310a and a second mounting region 310b, a Zener diode 320 mounted on the second mounting region 310b, a light emitting device 330 mounted on the first mounting region 310a, and a package body 340 surrounding the lead frame 310.

The lead frame 310 may include at least a first lead frame 311 and a second lead frame 312 formed as a pair and separated. The lead frame 310 may have a first surface and a second surface opposite to each other. The first surface may define a top surface of the lead frame 310 and the second surface may define a bottom surface of the lead frame 310.

The lead frame 310 may have a first mounting region 310a on which the light emitting device 330 is mounted. The lead frame 310 may have a recess portion 313 recessed to a predetermined depth from the first surface thereof such that the first mounting region 310a is surrounded by the recess portion 313. The recess portion 313 may accommodate a wire 321 therein.

The lead frame 310 may have the second mounting region 310b on which the Zener diode 320 is mounted. The second mounting region 310b may be positioned within the recess portion 313. The second mounting region 310b may be provided to penetrate through the bottom surface of the recess portion 313 on one side of either of the first and second lead frames 311 and 312. The second mounting region 310b may be disposed in a position lower than the first mounting region 310a with respect to the second surface opposing the first surface.

The configuration and structure of the lead frame 310 are substantially the same as those of the lead frame 110 of FIG. 1. Thus, detailed descriptions thereof will be omitted.

The Zener diode 320 may be attached and fixed within the second mounting region 310b of the second lead frame 312 through, for example, a conductive adhesive 360. The Zener diode 320 may be electrically connected to the first lead frame 311 through the wire 321. The conductive adhesive 360 may be, for example, a silver (Ag) epoxy.

The wire 321 may be accommodated in the recess portion 313 and extend to the first lead frame 311 along the recess portion 313.

The Zener diode 320 mounted in the second mounting region 310b of the lead frame 310 and the wire 321 accommodated within the recess portion 313 of the lead frame 310 may be positioned at a level lower than the first mounting region 310a.

The light emitting device 330 may be mounted on the first mounting region 310a. The light emitting device 330 may be electrically connected to the first and second lead frames 311 and 312 in a flipchip bonding manner using solder (S), for example. The light emitting device 330 may be disposed on the Zener diode 320 and the wire 321.

The package body 340 may allow the first and second lead frames 311 and 312 to be embedded therein and may be provided on the circumference of the lead frame 310 to fix the lead frame 310. The package body 340 may fill the recess portion 313 to cover and hermetically seal the Zener diode 320 and the wire 321, in the place of the encapsulant 140 of FIG. 1.

For an electrical connection with an external power source, the lead frame 310 may be exposed outwardly through a bottom surface of the package body 340.

The package body 340 may have an opening 341 having a reflective cup shape opened to expose the first mounting region 310a and the light emitting device 330 mounted on the first mounting region 310a. Inner lateral sides of the opening 341 may have a sloped tapered structure and may serve as reflective surfaces reflecting light from the light emitting device 330.

A lens unit 350 may be provided in the opening 341 to fill the opening 341. However, an outer appearance of the lens unit 350 may be different from that of the lens unit 150 according to the exemplary embodiment of FIG. 1. The lens unit 350 may be formed of a resin material having light transmittance and may contain a phosphor according to exemplary embodiments.

The package body 340 may be formed by injecting a resin such as polycarbonate (PC), polymethylmethacrylate (PMMA), acryl, or ABS, or an epoxy into a mold and solidifying the same. For example, a method such as injection molding, transfer molding, or compression molding may be used.

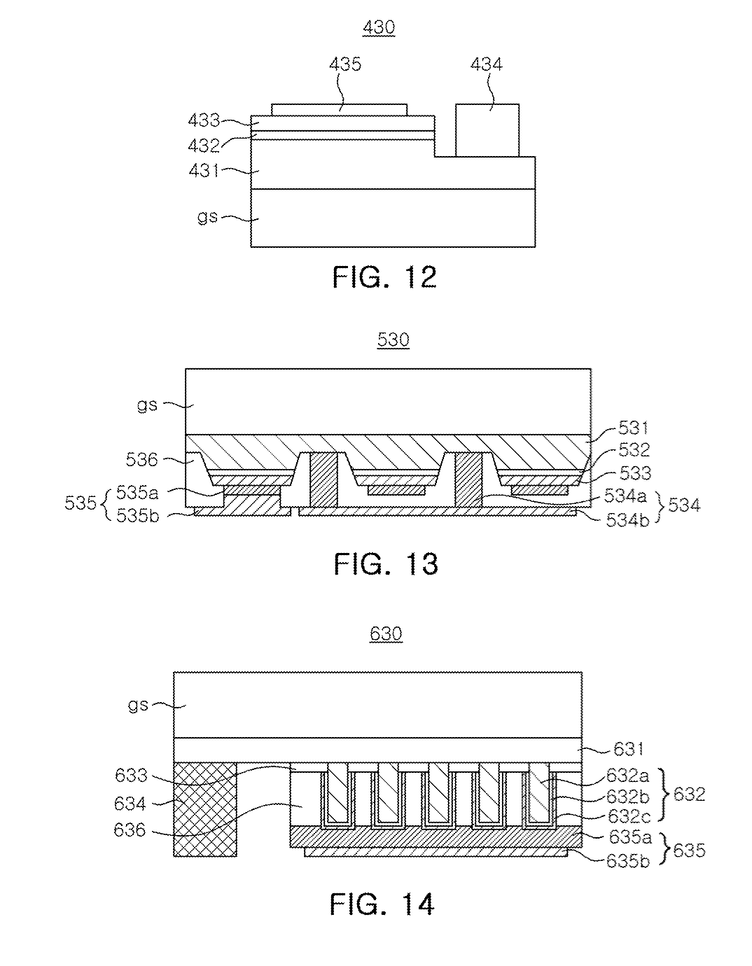

Various examples of LED chips employable in a light emitting device will be described with reference to FIGS. 12 through 14. FIGS. 12 through 14 are cross-sectional views illustrating various examples of light emitting diode (LED) chips employable in a light emitting device according to an exemplary embodiment of the present disclosure.

Referring to FIG. 12, an LED chip 430 may include a first conductivity-type semiconductor layer 431, an active layer 432, and a second conductivity-type semiconductor layer 433 sequentially stacked on a growth substrate gs.

The first conductivity-type semiconductor layer 431 stacked on the growth substrate gs may be an n-type nitride semiconductor layer doped with an n-type impurity. The second conductivity-type semiconductor layer 433 may be a p-type nitride semiconductor layer doped with a p-type impurity. However, according to exemplary embodiments, positions of the first and second conductivity-type semiconductor layers 431 and 433 may be interchanged so as to be stacked. The first and second conductivity-type semiconductor layers 431 and 433 may have an empirical formula AlₓIn_{y}Ga_{(1-x-y)}N, where 0≦x<1, 0≦y<1, and 0≦x+y<1, and, for example, materials such as GaN, AlGaN, InGaN, AlInGaN may correspond thereto.

The active layer 432 disposed between the first and second conductivity-type semiconductor layers 431 and 433 may emit light having a predetermined level of energy according to electron-hole recombination. The active layer 432 may include a material having an energy band gap smaller than those of the first and second conductivity-type semiconductor layers 431 and 433. For example, in a case in which the first and second conductivity-type semiconductor layers 431 and 433 are formed of a GaN-based compound semiconductor, the active layer 432 may include an InGaN-based compound semiconductor having an energy band gap smaller than that of GaN. Also, the active layer 432 may have a multi-quantum well (MQW) structure in which quantum well layers and quantum barrier layers are alternately stacked, for example, an InGaN/GaN structure. However, the structure of the active layer 432 is not limited thereto and the active layer 432 may have a single quantum well (SQW) structure.

The LED chip 430 may include first and second electrode pads 434 and 435 electrically connected to the first and second conductivity-type semiconductor layers 431 and 433, respectively. The first and second electrode pads 434 and 435 may be disposed and exposed to face in the same direction. The first and second electrode pads 434 and 435 may be electrically connected to a board through wire bonding or flipchip bonding.

An LED chip 530 illustrated in FIG. 13 may include a semiconductor stacked body formed on a growth substrate gs. The semiconductor stacked body may include a first conductivity-type semiconductor layer 531, an active layer 532, and a second conductivity-type semiconductor layer 533.

The LED chip 530 may include first and second electrode pads 534 and 535 respectively connected to the first and second conductivity-type semiconductor layers 531 and 533. The first electrode pad 534 may include a conductive via 534a connected to the first conductivity-type semiconductor layer 531 penetrating through the second conductivity-type semiconductor layer 533 and the active layer 532, and an electrode extending portion 534b connected to the conductive via 534a. The conductive via 534a may be surrounded by an insulating layer 536 so as to be electrically separated from the active layer 532 and the second conductivity-type semiconductor layer 533. The conductive via 534a may be disposed in a region formed by etching the semiconductor stacked body. The amount, shape, and pitch of conductive vias 534a, a contact area with the first conductivity-type semiconductor layer 531, and the like, may be appropriately designed such that contact resistance is reduced. The conductive vias 534a are arranged in rows and columns on the semiconductor stacked body, improving current flow. The second electrode pad 535 may include an ohmic contact layer 535a and an electrode extending portion 535b on the second conductivity-type semiconductor layer 533.

A LED chip 630 illustrated in FIG. 14 includes a growth substrate gs, a first conductivity-type base layer 631 formed on the growth substrate gs, and a plurality of light emitting nanostructures 632 formed on the first conductivity-type base layer 631. The LED chip 630 may further include an insulating layer 633 and a filler portion 636.

Each of the plurality of light emitting nanostructures 632 includes a first conductivity-type semiconductor core 632a, and an active layer 632b and a second conductivity-type semiconductor layer 632c sequentially formed as shell layers on the surface of the first conductivity-type semiconductor core 632a.

In the present exemplary embodiment, it is illustrated that each of the light emitting nanostructures 632 has a core-shell structure, but the structure of the light emitting nanostructures 632 is not limited thereto and each of the light emitting nanostructures 632 may have any other structure such as a pyramid structure. The first conductivity-type semiconductor base layer 631 may be a layer providing a growth surface for the light emitting nanostructures 632. The insulating layer 633 may provide an open region allowing the light emitting nanostructures 632 to be grown, and may be formed of a dielectric material such as SiO₂ or SiNₓ. The filler portion 636 may structurally stabilize the light emitting nanostructures 632 and allows light to be transmitted or reflected. Alternatively, in a case in which the filler portion 636 includes a light-transmissive material, the filler portion 636 may be formed of a transparent material such as SiO₂, SiNx, an elastic resin, silicon, an epoxy resin, a polymer, or plastic. If necessary, in a case in which the filler portion 636 includes a reflective material, the filler portion 636 may be formed of metal powder or ceramic powder having high reflectivity mixed with a polymer material such as polypthalamide (PPA), or the like. The highly reflective ceramic powder may be at least one selected from the group consisting of TiO₂, Al₂O₃, Nb₂O₅, Al₂O₃, and ZnO. Alternatively, a highly reflective metal such as aluminum (Al) or silver (Ag) may be used.

The first and second electrode pads 634 and 635 may be disposed on lower surfaces of the light emitting nanostructures 632. The first electrode pad 634 is positioned on an exposed upper surface of the first conductivity-type semiconductor base layer 631, and the second electrode pad 635 includes an ohmic contact layer 635a and an electrode extending portion 635b formed below the light emitting nanostructures 632 and the filler portion 636. Alternatively, the ohmic contact layer 635a and the electrode extending portion 635b may be integrally formed.

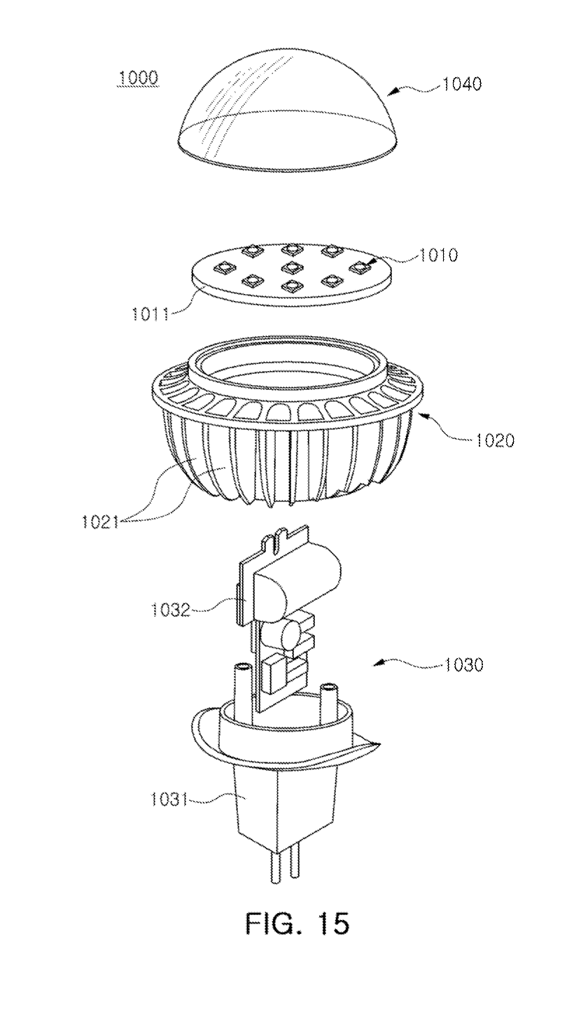

Lighting devices according to various examples employing a light emitting device package according to an exemplary embodiment of the present disclosure will be described with reference to FIGS. 15 through 17.

FIG. 15 is an exploded perspective view schematically illustrating a lighting device according to an exemplary embodiment of the present disclosure.

Referring to FIG. 15, a lighting device 1000 according to an exemplary embodiment of the present disclosure may be a bulb-type lamp and may be used as an indoor lighting device, for example, a downlight.

The lighting device 1000 may include a housing 1020 having an electrical connection structure 1030 and at least one light emitting device package 1010 mounted on the housing 1020. The lighting device 1000 may further include a cover 1040 covering the at least one light emitting device package 1010.

The light emitting device package 1010 may be substantially the same as the light emitting device package 10 illustrated in FIG. 1, and thus, a detailed description thereof will be omitted. The light emitting device package 1010 may have a configuration in which a plurality of light emitting devices and lenses are installed and disposed on a board 1011.

The housing 1020 serves both as a frame supporting the light emitting device package 1010 and as a heat sink outwardly dissipating heat generated by the light emitting device package 1010. To this end, the housing 1020 may be formed of a material being substantial (rigid, sturdy, or solid) and having high heat conductivity. For example, the housing 1020 may be formed of a metal material such as aluminum (Al), or a heat dissipation resin.

A plurality of heat dissipation fins 1021 may be provided on an outer surface of the housing 1020 in order to increase a contact area with surrounding air to enhance heat dissipation efficiency.

The housing 1020 has the electrical connection structure 1030 electrically connected to the light emitting device package 1010. The electrical connection structure 1030 may include a terminal unit 1031 and a driving unit 1032 supplying driving power supplied through the terminal unit 1031 to the light emitting device package 1010.

The terminal unit 1031 serves to allow the lighting device 1000 to be fixedly installed in, for example, a socket, or the like, so as to be electrically connected. In the present exemplary embodiment, the terminal unit 1031 is illustrated as having a slidably inserted pin-type structure, but the type of the terminal unit 1031 is not limited thereto. If necessary, the terminal unit 1031 may have an Edison type structure having threads going around to be inserted.

The driving unit 1032 serves to convert external driving power into a current source appropriate for driving the light emitting device package 1010, and provide the same. The driving unit 1032 may be configured as, for example, an AC-DC converter, a rectifying circuit component, or a fuse. Also, the driving unit 1032 may further include a communications module realizing remote controlling according to circumstances.

The cover 1040 may be installed on the housing 1020 to cover the light emitting device package 1010 and have a convex lens shape or a bulb shape. The cover 1040 may be formed of a light-transmissive material and contain a light dispersion material.

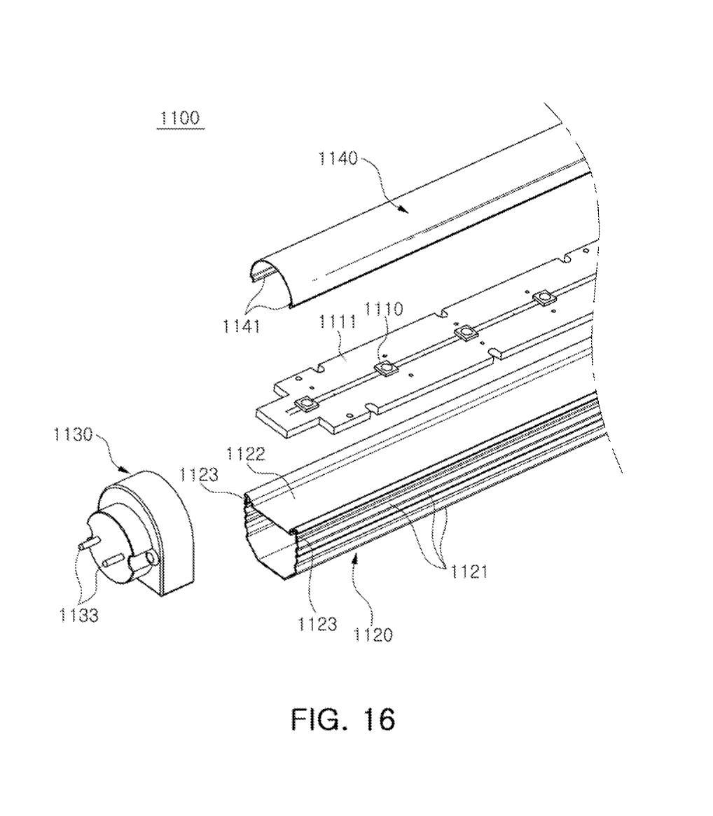

FIG. 16 is an exploded perspective view schematically illustrating a lighting device according to another exemplary embodiment of the present disclosure. Referring to FIG. 16, a lighting device 1100 may be, for example, a bar-type lamp and include a light emitting device package 1110, a housing 1120, a terminal 1130, and a cover 1140.

As the light emitting device package 1110, the light emitting device package illustrated in FIG. 1 may be employed, so a detailed description thereof will be omitted. A plurality of light emitting device packages 1110 may be mounted and arranged on a board 1111.

The board 1111 on which the light emitting device packages 1110 are mounted may be fixedly mounted on one surface 1122 of the housing 1120. The housing 1120 may dissipate heat generated by the light emitting device packages 1110 outwardly. To this end, the housing 1120 may be formed of a material having excellent thermal conductivity, for example, a metal, and a plurality of heat dissipation fins 1121 may protrude from both lateral surfaces of the housing 1120 to dissipate heat.

The cover 1140 is fastened to stoppage grooves 1123 of the housing 1120 to cover the light emitting device packages 1110. The cover 1140 may have a semicircular curved surface to allow light generated by the light emitting device packages 1110 to be uniformly radiated to the outside overall. Protrusions 1141 may be formed in a longitudinal direction on a bottom surface of the cover 1140 and engaged with the stoppage grooves 1123 of the housing 1120.

The terminal 1130 may be provided on at least one open side, among both end portions of the housing 1120 in a longitudinal direction, to supply power to the light emitting device packages 1110 and include electrode pins 1133 protruding outwardly.

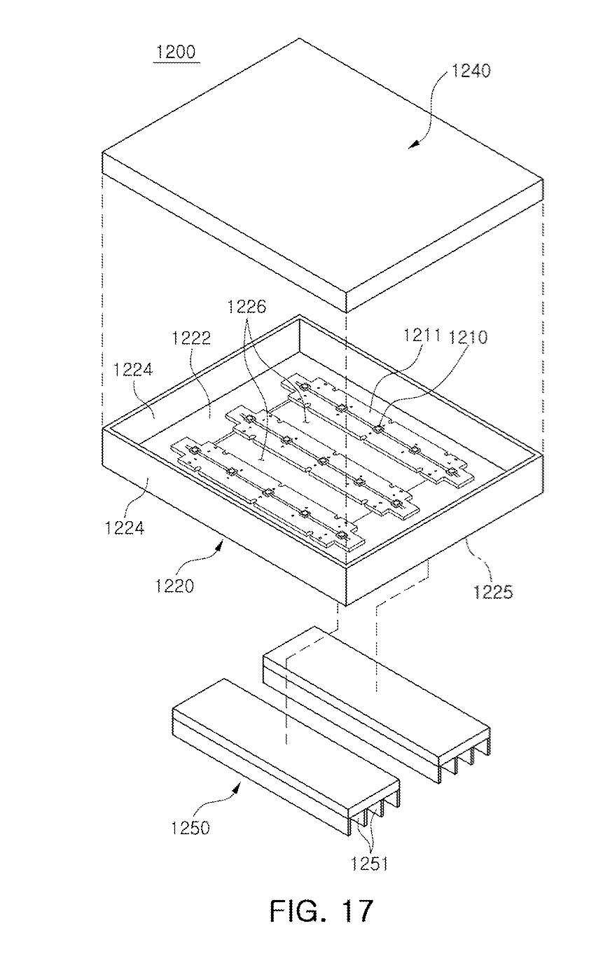

FIG. 17 is an exploded perspective view schematically illustrating a lighting device according to another exemplary embodiment of the present disclosure. Referring to FIG. 17, a lighting device 1200 may have, for example, a surface light source-type structure and include light emitting device packages 1210, a housing 1220, a cover 1240, and heat sinks 1250.

As the light emitting device packages 1210, the light emitting device package illustrated in FIG. 1 may be employed, so a detailed description thereof will be omitted. A plurality of light emitting device packages 1210 may be mounted and arranged on boards 1211.

The housing 1220 may have a box-shaped structure including one surface 1222 on which the light emitting device packages 1210 are mounted and lateral surfaces 1224 extending from the circumference of the one surface 1222. The housing 1220 may be formed of a material having excellent thermal conductivity, for example, a metal, that may dissipate heat generated by the light emitting device packages 1210 outwardly.

A hole 1226 to which the heat sinks 1250 (to be described hereinafter) are insertedly fastened may be formed in the one surface 1222 of the housing 1220 in a penetrating manner. The boards 1211 mounted on the one surface 1222 may partially span the hole 1226 so as to be exposed to the outside.

The cover 1240 may be fastened to the housing 1220 to cover the light emitting device packages 1210. The cover 1240 may have an overall flat structure.

The heat sinks 1250 may be fastened to the hole 1226 through the other surface 1225 of the housing 1220. The heat sinks 1250 may be in contact with the light emitting device packages 1210 through the hole 1226 to dissipate heat from the light emitting device packages 1210 outwardly. In order to increase heat dissipation efficiency, the heat sinks 1250 may have a plurality of heat dissipation fins 1251. The heat sinks 1250 may be formed of a material having excellent thermal conductivity, like the housing 1220.

A lighting device using a light emitting device may be applied to an indoor lighting device or an outdoor lighting device according to the purposes thereof. The indoor LED lighting device may include a bulb-type lamp, a fluorescent lamp (LED-tube), or a flat panel type lighting device replacing an existing lighting fixture (retrofit), and the outdoor LED lighting device may include a streetlight, a security light, a floodlight, a scenery lamp, a traffic light, and the like.

Also, the lighting device using LEDs may be utilized as an internal or external light source of a vehicle. As an internal light source, the LED lighting device may be used as an indoor light, as a reading light, or as various dashboard light sources of a vehicle. As an external light source of a vehicle, the LED lighting device may be used as a headlight, a brake light, a turn signal lamp, a fog light, a running light, and the like.

In addition, the LED lighting device may also be applicable as a light source used in robots or various mechanic facilities. In particular, LED lighting using light within a particular wavelength band may promote plant growth and stabilize a person's mood or treat diseases using emotional lighting.

As set forth above, according to exemplary embodiments of the present disclosure, a light emitting device package in which optical and mechanical interference of a Zener diode is eliminated without increasing a size of the package may be provided.

While exemplary embodiments have been shown and described above, it will be apparent to those skilled in the art that modifications and variations could be made without departing from the scope of the present invention as defined by the appended claims.

What is claimed is:

1. A light emitting device package comprising:
a lead frame having one surface with a recess portion provided therein and including a first mounting region positioned on the one surface and a second mounting region positioned in the recess portion;
a light emitting device mounted on the first mounting region and electrically connected to the lead frame; and
a Zener diode mounted on the second mounting region and connected to the lead frame by a wire,
wherein the wire is positioned within the recess portion and is disposed to have a height lower than the first mounting region.

2. The light emitting device package of claim 1, wherein the light emitting device is disposed on the Zener diode and the wire.

3. The light emitting device package of claim 1, wherein the recess portion is disposed to surround the first mounting region.

4. The light emitting device package of claim 1, further comprising an encapsulant filling the recess portion and covering the Zener diode and the wire.

5. The light emitting device package of claim 4, wherein the encapsulant includes a reflective powder.

6. The light emitting device package of claim 1, wherein the recess portion is recessed from the one surface of the lead frame and has a bottom surface forming a step with respect to the first mounting region.

7. The light emitting device package of claim 6, wherein a bottom surface of the second mounting region has a level lower than the other region of the bottom surface of the recess portion.

8. The light emitting device package of claim 6, wherein the Zener diode has a first electrode disposed on a lower surface thereof and a second electrode disposed on an upper surface thereof, and the first electrode is connected to one region of the lead frame through the bottom surface of the recess portion and the second electrode is connected to the other region of the lead frame through the wire.

9. The light emitting device package of claim 8, wherein the Zener diode is attached to the bottom surface of the second mounting region by a conductive material.

10. The light emitting device package of claim 1, wherein the second mounting region is a region penetrating through the lead frame, and includes a conductive material partially filling the penetrated region to provide a bottom surface of the second mounting region on which the Zener diode is mounted.

11. The light emitting device package of claim 10, wherein the Zener diode has a first electrode disposed on a lower surface thereof and a second electrode disposed on an upper surface thereof, and the first electrode is connected to one region of the lead frame through the conductive material and the second electrode is connected to the other region of the lead frame through the wire.

12. The light emitting device package of claim 1, wherein the lead frame comprises separated first and second lead frames, and the recess portion is disposed in at least one of the first and second lead frames.

13. The light emitting device package of claim 12, wherein the second mounting region is positioned on one side of either of the first and second lead frames.

14. The light emitting device package of claim 12, further comprising an encapsulant filling the recess portion and covering the Zener diode and the wire, wherein the encapsulant binds the first and second lead frames.

15. A light emitting device package comprising:
first and second lead frames disposed to be spaced apart from one another;
a light emitting device disposed on at least one of the first and second lead frames;
a Zener diode disposed on the second lead frame and connected to the first lead frame by a wire; and
an encapsulant binding the first and second lead frames,
wherein the Zener diode is mounted in a region penetrating through the lead frame on a bottom surface of a recess portion provided in the second lead frame, and the wire is positioned within the recess portion to have a level lower than the light emitting device.

16. A package, comprising:
a lead frame having a recess;
a Zener diode disposed in the recess of the lead frame; and
a light emitting device disposed on the Zener diode.

17. The package of claim 16, wherein one electrode of the Zener diode is electrically connected to the lead frame via a wire disposed in the recess and covered by the light emitting device.

18. The package of claim 17, further comprising an encapsulant filling the recess and covering the Zener diode and the wire.

19. The package of claim 17, further comprising a light transmissive lens unit,
wherein the lens unit does not contact any of the Zener diode and the wire.

20. The package of claim 17, wherein the lead frame includes a hole penetrating through the bottom of the recess and the Zener diode is disposed in the hole.
